(19) United States
(12) Patent Application Publication
(10) Pub. No.: US 2024/0113668 A1
(43) Pub. Date: Apr. 4, 2024

(54) AMPLIFIER CIRCUIT AND RADIO FREQUENCY CIRCUIT

(71) Applicant: Murata Manufacturing Co., Ltd., Nagaokakyo-shi (JP)

(72) Inventors: Kenji TAHARA, Nagaokakyo-shi (JP); Kae YAMAMOTO, Nagaokakyo-shi (JP); Yoshiaki SUKEMORI, Nagaokakyo-shi (JP)

(73) Assignee: Murata Manufacturing Co., Ltd., Nagaokakyo-shi (JP)

(21) Appl. No.: 18/528,810

(22) Filed: Dec. 5, 2023

Related U.S. Application Data
(63) Continuation of application No. PCT/JP2022/021757, filed on May 27, 2022.

(30) Foreign Application Priority Data
Jun. 10, 2021 (JP) 2021-097434

(51) Int. Cl. H03F 3/24; H03F 3/66

(52) U.S. Cl. CPC H03F 3/24; H03F 3/66; H03F 2200/171; H03F 2200/451; H03F 2200/541

(57) ABSTRACT

An amplifier circuit includes amplifiers, transformers, and a transmission line. A first end of an input-side coil is connected to an output terminal of the amplifier, a second end of the input-side coil is connected to an output terminal of the amplifier via the transmission line, a first end of an input-side coil is connected to an output terminal of the amplifier, a second end of the input-side coil is connected to the output terminal of the amplifier via the transmission line, a first end of an output-side coil is connected to an output terminal, a second end of the output-side coil is connected to a ground, a first end of an output-side coil is connected to an output terminal, and a second end of the output-side coil is connected to the ground.

### CROSS-REFERENCE TO RELATED APPLICATIONS

This is a continuation application of PCT/JP2022/021757, filed on May 27, 2022, designating the United States of America, which is based on and claims priority to Japanese Patent Application No. JP 2021-097434 filed on Jun. 10, 2021. The entire contents of the above-identified applications, including the specifications, drawings and claims, are incorporated herein by reference in their entirety.

### TECHNICAL FIELD

The present disclosure relates to an amplifier circuit and a radio frequency circuit.

### BACKGROUND ART

In a mobile communication device, such as a mobile phone, the radio frequency front-end module has become complex particularly along with the development of multiband technology.

Patent Document 1 discloses a power amplifier circuit including a first amplifier (carrier amplifier) that amplifies a first signal, which is obtained by splitting an input signal in a region in which the power level of the input signal is greater than or equal to a first level and outputs the amplified first signal as a second signal; a first transformer that receives the second signal; a second amplifier (peak amplifier) that amplifies a third signal, which is obtained by splitting the input signal in a region in which the power level of the input signal is greater than or equal to a second level higher than the first level and outputs the amplified third signal as a fourth signal; and a second transformer that receives the fourth signal.

### CITATION LIST

### Patent Document

Patent Document 1: Japanese Unexamined Patent Application Publication No. 2018-137566

### SUMMARY OF DISCLOSURE

### Technical Problem

However, based on the amplifier circuit disclosed in Patent Document 1 is applied to a multiband system and the amplifier circuit is provided for each band, the number of amplifiers increases. On the other hand, based on one amplifier circuit is used for multiple bands, the amplification characteristics may be degraded.

For the above reasons, the present disclosure provides an amplifier circuit and a radio frequency circuit that, in multiband applications, can suppress the increase in the number of amplifiers and also reduce the deterioration of amplification characteristics.

### Solution to Problem

According to an aspect of the present disclosure, an amplifier circuit includes a first output terminal and a second output terminal; a first amplifier, a second amplifier, and a third amplifier; a first transformer including a first input-side coil and a first output-side coil; a second transformer including a second input-side coil and a second output-side coil; and a transmission line connected to an output terminal of the second amplifier. A first end of the first input-side coil is connected to an output terminal of the first amplifier; a second end of the first input-side coil is connected to the output terminal of the second amplifier via the transmission line; a first end of the second input-side coil is connected to an output terminal of the third amplifier; a second end of the second input-side coil is connected to the output terminal of the second amplifier via the transmission line; a first end of the first output-side coil is connected to the first output terminal; a second end of the first output-side coil is connected to a ground; a first end of the second output-side coil is connected to the second output terminal; and a second end of the second output-side coil is connected to the ground.

According to an aspect of the present disclosure, an amplifier circuit includes a first output terminal and a second output terminal; a first amplifier, a second amplifier, and a third amplifier; a first transformer including a first input-side coil and a first output-side coil; a second transformer including a second input-side coil and a second output-side coil; a third transformer including a third input-side coil and a third output-side coil; a first transmission line connected to an output terminal of the first amplifier; a second transmission line connected to an output terminal of the second amplifier; and a third transmission line connected to an output terminal of the third amplifier. A first end of the first input-side coil is connected to the output terminal of the first amplifier via the first transmission line; a second end of the first input-side coil is connected to a ground; a first end of the first output-side coil is connected to the first output terminal; a first end of the second input-side coil is connected to the output terminal of the second amplifier via the second transmission line; a second end of the second input-side coil is connected to the ground; a first end of the second output-side coil is connected to a second end of the first output-side coil; a first end of the third input-side coil is connected to the output terminal of the third amplifier via the third transmission line; a second end of the third input-side coil is connected to the ground; a first end of the third output-side coil is connected to a second end of the second output-side coil; and a second end of the third output-side coil is connected to the second output terminal.

### Advantageous Effects of Disclosure

An aspect of the present disclosure provides an amplifier circuit that, in multiband applications, can suppress the increase in the number of amplifiers and also reduce the deterioration of amplification characteristics.

### BRIEF DESCRIPTION OF DRAWINGS

FIG. 1 is a circuit diagram of an amplifier circuit, a radio frequency circuit, and a communication device according to a first embodiment.

FIG. 2A is a circuit diagram of a carrier amplifier according to the first embodiment.

FIG. 2B is a circuit diagram of a peak amplifier according to the first embodiment.

FIG. 3 is a circuit state diagram of the amplifier circuit according to the first embodiment based on a large signal in a band A being input.

FIG. 4 is a circuit state diagram of the amplifier circuit according to the first embodiment based on a small signal in the band A being input.

FIG. 5 is a circuit state diagram of the amplifier circuit according to the first embodiment based on a large signal in a band B being input.

FIG. 6 is a circuit state diagram of the amplifier circuit according to the first embodiment based on a small signal in the band B being input.

FIG. 7A is a plan view of the amplifier circuit according to the first embodiment.

FIG. 7B is a cross-sectional view of the amplifier circuit according to the first embodiment.

FIG. 8 is a circuit diagram of an amplifier circuit, a radio frequency circuit, and a communication device according to a first variation of the first embodiment.

FIG. 9 is a circuit diagram of an amplifier circuit, a radio frequency circuit, and a communication device according to a second variation of the first embodiment.

FIG. 10 is a circuit diagram of an amplifier circuit, a radio frequency circuit, and a communication device according to a second embodiment.

FIG. 11 is a circuit state diagram of the amplifier circuit according to the second embodiment based on a large signal in the band A being input.

FIG. 12 is a circuit state diagram of the amplifier circuit according to the second embodiment based on a small signal in the band A being input.

FIG. 13 is a circuit state diagram of the amplifier circuit according to the second embodiment based on a large signal in the band B being input.

FIG. 14 is a circuit state diagram of the amplifier circuit according to the second embodiment based on a small signal in the band B being input.

FIG. 15A is a plan view of the amplifier circuit according to the second embodiment.

FIG. 15B is a cross-sectional view of the amplifier circuit according to the second embodiment.

FIG. 16 is a circuit diagram of an amplifier circuit, a radio frequency circuit, and a communication device according to a first variation of the second embodiment.

FIG. 17 is a circuit diagram of an amplifier circuit, a radio frequency circuit, and a communication device according to a second variation of the second embodiment.

### DESCRIPTION OF EMBODIMENTS

Embodiments of the present disclosure are described below with reference to the drawings. Each of the embodiments described below represents a general or specific example. Values, shapes, materials, components, and the layouts and connection configurations of the components described in the embodiments below are just examples and are not intended to limit the present disclosure.

Each of the drawings is a schematic diagram in which components are emphasized or omitted and the ratios between the components are adjusted to facilitate the understanding of the present disclosure. That is, components in each of the drawings are not necessarily illustrated accurately; and the shapes, the positional relationships, and the ratios of the components may differ from the actual shapes, positional relationships, and ratios. The same reference number is assigned to substantially the same components in the drawings, and repeated descriptions of those components may be omitted or simplified.

In each of the drawings below, an x-axis and a y-axis are orthogonal to each other in a plane that is parallel to the major surface of a module substrate. Specifically, based on the module substrate having a rectangular shape in plan view, the x-axis is parallel to a first side of the module substrate, and the y-axis is parallel to a second side of the module substrate that is orthogonal to the first side. Also, a z-axis is perpendicular to the major surface of the module substrate, a positive z-axis direction indicates an upward direction, and a negative z-axis direction indicates a downward direction.

In circuit configurations of the present disclosure, “connected” not only indicates that circuit elements are directly connected to each other with a connection terminal and/or a wire conductor but also indicates that the circuit elements are electrically connected to each other via another circuit element. Also, “connected between A and B” indicates that a component is disposed between A and B and connected to both of A and B. Specifically, “connected between A and B” not only indicates that a component is connected in series with A and B in a path connecting A and B but also indicates that a component is connected in parallel with (in shunt connection with) A and B at a position between the path and a ground.

In layouts of components of the present disclosure, “plan view” indicates a view of an object that is orthographically projected onto an xy plane from the positive z-axis side. “A is disposed between B and C” indicates that at least one of multiple line segments connecting given points in B and given points in C passes through A. Also, terms such as “parallel” and “perpendicular” indicating relationships between elements, terms such as “rectangular” indicating shapes of elements, and numerical ranges do not only indicate their exact meanings but may also indicate substantially equivalent ranges that differ by, for example, about a few percent.

### First Embodiment

### [1.1 Circuit Configurations of Communication Device 5, Radio Frequency Circuit 1, and Amplifier Circuit 10]

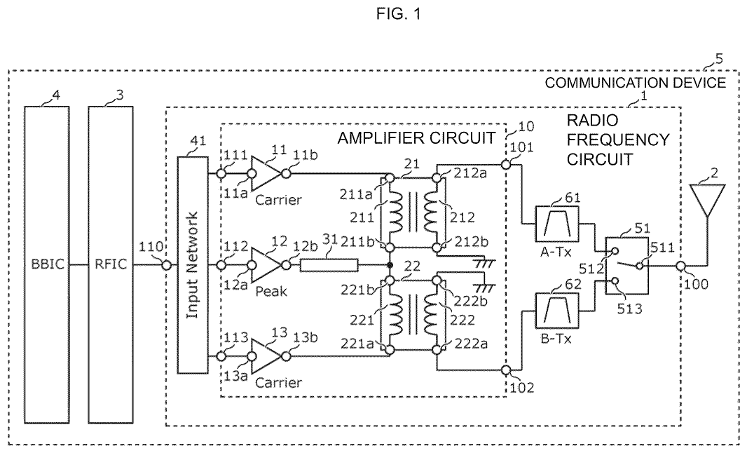

Circuit configurations of a communication device 5, a radio frequency circuit 1, and an amplifier circuit 10 according to a first embodiment are described below with reference to FIG. 1. FIG. 1 is a circuit diagram of the amplifier circuit 10, the radio frequency circuit 1, and the communication device 5 according to the present embodiment.

### [1.1.1 Circuit Configuration of Communication Device 5]

First, a circuit configuration of the communication device 5 is described. As illustrated in FIG. 1, the communication device 5 according to the present embodiment includes the radio frequency circuit 1, an antenna 2, a radio frequency integrated circuit (RFIC) 3, and a baseband integrated circuit (BBIC) 4.

The radio frequency circuit 1 transmits radio frequency signals between the antenna 2 and the RFIC 3. The internal configuration of the radio frequency circuit 1 is described later.

The antenna 2 is connected to an antenna connection terminal 100 of the radio frequency circuit 1 and transmits a radio frequency signal output from the radio frequency circuit 1.

The RFIC 3 is an example of a signal processing circuit that processes radio frequency signals. Specifically, the RFIC 3 performs signal processing, such as up-converting, on a transmission signal input from the BBIC 4 and outputs a radio frequency transmission signal generated by the signal processing to the radio frequency circuit 1. The RFIC 3 includes a control unit that controls, for example, switches and amplifiers of the radio frequency circuit 1. Some or all of the functions of the control unit of the RFIC 3 may be provided outside of the RFIC 3 and may be implemented by, for example, a component in the BBIC 4 or the radio frequency circuit 1.

The BBIC4 is a baseband signal processing circuit that performs signal processing using an intermediate frequency band that is lower than the frequency of radio frequency signals transmitted by the radio frequency circuit 1. For example, a signal processed by the BBIC 4 is used as an image signal for displaying an image and/or a voice signal for a call via a speaker.

In the communication device 5 according to the present embodiment, the antenna 2 and the BBIC 4 may or may not be optional components.

### [1.1.2 Circuit Configuration of Radio Frequency Circuit 1]

Next, a circuit configuration of the radio frequency circuit 1 is described. As illustrated in FIG. 1, the radio frequency circuit 1 includes an amplifier circuit 10, an input network 41, a switch 51, filters 61 and 62, an antenna connection terminal 100, and a radio frequency input terminal 110. Components of the radio frequency circuit 1 are described in sequence below.

The radio frequency input terminal 110 receives a radio frequency transmission signal from outside of the radio frequency circuit 1. The radio frequency input terminal 110 is connected to the RFIC 3 at a position outside of the radio frequency circuit 1 and is connected to the input network 41 at a position inside of the radio frequency circuit 1. The radio frequency input terminal 110 is capable of receiving transmission signals in bands A and B from the RFIC 3.

The input network 41 splits an input signal received via the radio frequency input terminal 110 and outputs signals obtained by splitting the input signal to the amplifier circuit 10. In the present embodiment, the input network 41 adjusts the phases of the obtained signals.

Specifically, the input network 41 splits an input signal in the band A received via the radio frequency input terminal 110 into two signals (split signals) in the band A and outputs the two split signals in the band A to the input terminals 111 and 112 of the amplifier circuit 10. In this process, the input network 41 adjusts the phases of the two split signals in the band A. For example, the input network 41 shifts the split signal in the band A to be output to the input terminal 111 by −90 degrees (or delays the split signal by 90 degrees) relative to the input signal and shifts the split signal in the band A to be output to the input terminal 112 by +180 degrees (or advances the split signal by 180 degrees) relative to the input signal.

Also, the input network 41 splits an input signal in the band B received via the radio frequency input terminal 110 into two signals (split signals) in the band B and outputs the two split signals in the band B to the input terminals 113 and 112 of the amplifier circuit 10. In this process, the input network 41 adjusts the phases of the two split signals in the band B. For example, the input network 41 shifts the split signal in the band B to be output to the input terminal 113 by −90 degrees (or delays the split signal by 90 degrees) relative to the input signal and shifts the split signal in the band B to be output to the input terminal 112 by +180 degrees (or advances the split signal by 180 degrees) relative to the input signal.

The amounts of phase shift caused by the input network 41 are not limited to those described above. The amounts of phase shift may be set freely as long as the relative phase difference between two split signals is maintained. For example, the amounts of phase shift of two split signals may be 0 degree and +270 degrees. Also, the phase difference between two split signals may also be changed as appropriate based on the internal configuration of the amplifier circuit 10.

For example, the input network 41 may be implemented by a quadrature coupler.

The amplifier circuit 10 is a Doherty amplifier circuit and is capable of amplifying transmission signals in the bands A and B. Here, a Doherty amplifier circuit is implemented by combining two amplifiers (for example, a class A amplifier (including a class AB amplifiers) and a class C amplifier) to achieve high efficiency. In a Doherty amplifier circuit, one or both of output terminals of two amplifiers are connected to transmission lines. With this configuration, the load impedance seen from the class A amplifier changes according to the output power level, and the efficiency at the low power level is improved. The internal configuration of the amplifier circuit 10 is described later.

A filter 61 (A-Tx) is an example of a first filter and is connected between an output terminal 101 of the amplifier circuit 10 and the antenna connection terminal 100. Specifically, one end of the filter 61 is connected to the antenna connection terminal 100 via the switch 51. On the other hand, another end of the filter 61 is connected to the output terminal 101 of the amplifier circuit 10.

The filter 61 has a pass band including the band A. Specifically, based on the band A being used for frequency division duplex (FDD), the pass band of the filter 61 includes an uplink operation band of the band A. Also, based on the band A being used for time division duplex (TDD), the pass band of the filter 61 includes the band A. Thus, the filter 61 can pass a transmission signal in the band A.

The filter 62 (B-Tx) is an example of a second filter and is connected between an output terminal 102 of the amplifier circuit 10 and the antenna connection terminal 100. Specifically, one end of the filter 62 is connected to the antenna connection terminal 100 via the switch 51. On the other hand, another end of the filter 62 is connected to the output terminal 102 of the amplifier circuit 10.

The filter 62 has a pass band including the band B. Specifically, based on the band B being used for FDD, the pass band of the filter 62 includes an uplink operating band of the band B. Also, based on the band B being used for TDD, the pass band of the filter 62 includes the band B. Thus, the filter 62 can pass a transmission signal in the band B.

Each of the filters 61 and 62 may be implemented by, but is not limited to, a surface acoustic wave (SAW) filter, a bulk acoustic wave (BAW) filter, an LC resonant filter, or a dielectric filter.

The bands A and B are examples of first and second bands and are frequency bands used for a communication system constructed using radio access technology (RAT). The bands A and B are predefined by, for example, a standardization organization (e.g., the 3rd Generation Partnership Project (3GPP) (registered trademark) or the Institute of Electrical and Electronics Engineers (IEEE)). Examples of communication systems include a 5th Generation New Radio (5G NR) system, a Long Term Evolution (LTE) system, and a wireless local area network (WLAN) system.

For example, a combination of n77 and n79 for 5G NR may be used as the combination of the bands A and B. However, the combination of the bands A and B is not limited to this example. As another example, Band 3 and Band 1 for LTE may also be used as the combination of the bands A and B. As still another example, Band 40 and Band 41 for LTE may also be used as the combination of the bands A and B.

The switch 51 is connected between the antenna connection terminal 100 and the filters 61 and 62. The switch 51 includes terminals 511 through 513. The terminal 511 is connected to the antenna connection terminal 100. The terminal 512 is connected to the filter 61. The terminal 513 is connected to the filter 62.

With this connection configuration, the switch 51 is capable of connecting the terminal 511 to one of the terminal 512 and the terminal 513 based on, for example, a control signal from the RFIC 3. In other words, the switch 51 is capable of connecting the antenna connection terminal 100 selectively to one of the filters 61 and 62. The switch 51 is implemented by, for example, a Single-Pole Double-Throw (SPDT) switch circuit and may also be referred to as an antenna switch.

The antenna connection terminal 100 is connected to the switch 51 at a position inside of the radio frequency circuit 1 and is connected to the antenna 2 at a position outside of the radio frequency circuit 1. Transmission signals in the bands A and B amplified by the amplifier circuit 10 are output to the antenna 2 via the antenna connection terminal 100.

The configuration of the radio frequency circuit 1 is not limited to the example illustrated in FIG. 1. As another example, the radio frequency circuit 1 may be configured to not include the switch 51 and the input network 41. Also, for example, the radio frequency circuit 1 may include filters and an amplifier circuit that support bands different from the bands A and B. As still another example, the radio frequency circuit 1 may further include a reception circuit.

### [1.1.3 Circuit Configuration of Amplifier Circuit 10]

Next, a circuit configuration of the amplifier circuit 10 is described. As illustrated in FIG. 1, the amplifier circuit 10 includes amplifiers 11 through 13, transformers 21 and 22, a transmission line 31, input terminals 111 through 113, and output terminals 101 and 102. Components of the amplifier circuit 10 are described below in sequence.

The input terminals 111 through 113 receive signals from the input network 41. Transmission signals in the band A output from the input network 41 are input to the amplifiers 11 and 12 via the input terminals 111 and 112. Also, transmission signals in the band B output from the input network 41 are input to the amplifiers 12 and 13 via the input terminals 112 and 113.

The amplifier 11 is an example of a first amplifier and is capable of amplifying a signal in the band A. In a Doherty amplifier circuit, the amplifier 11 functions as a carrier amplifier dedicated for the band A. The amplifier 11 includes an input terminal 11a and an output terminal 11b. The input terminal 11a is connected to the input terminal 111 of the amplifier circuit 10. The output terminal 11b is connected to the transformer 21.

The amplifier 12 is an example of a second amplifier and is capable of amplifying signals in the bands A and B. In a Doherty amplifier circuit, the amplifier 12 functions as a peak amplifier used for both of the bands A and B. The amplifier 12 includes an input terminal 12a and an output terminal 12b. The input terminal 12a is connected to the input terminal 112 of the amplifier circuit 10. The output terminal 12b is connected to the transformers 21 and 22 via the transmission line 31.

The amplifier 13 is an example of a third amplifier and is capable of amplifying a signal in the band B. In a Doherty amplifier circuit, the amplifier 13 functions as a carrier amplifier dedicated for the band B. The amplifier 13 includes an input terminal 13a and an output terminal 13b. The input terminal 13a is connected to the input terminal 113 of the amplifier circuit 10. The output terminal 13b is connected to the transformer 22.

Here, a carrier amplifier indicates an amplifier that operates regardless of whether the power of a radio frequency signal is low or high (e.g., relative to a power threshold). A peak amplifier indicates an amplifier that operates only based on the power of a radio frequency signal being high. Accordingly, based on the power of a radio frequency signal being low, the radio frequency signal is amplified by a carrier amplifier; and based on the power of a radio frequency signal being high, the radio frequency signal is amplified by a carrier amplifier and a peak amplifier, and resulting signals are combined. A carrier amplifier may be implemented by a class A amplifier (including a class AB amplifier), and a peak amplifier may be implemented by a class C amplifier.

The transformer 21 is an example of a first transformer. The transformer 21 includes an input-side coil 211 and an output-side coil 212.

The input-side coil 211 is an example of a first input-side coil. A first end 211a of the input-side coil 211 is connected to the output terminal 11b of the amplifier 11, and a second end 211b of the input-side coil 211 is connected to the output terminal 12b of the amplifier 12 via the transmission line 31.

The output-side coil 212 is an example of a first output-side coil. A first end 212a of the output-side coil 212 is connected to the output terminal 101 of the amplifier circuit 10, and a second end 212b of the output-side coil 212 is connected to the ground.

The transformer 22 is an example of a second transformer. The transformer 22 includes an input-side coil 221 and an output-side coil 222.

The input-side coil 221 is an example of a second input-side coil. A first end 221a of the input-side coil 221 is connected to the output terminal 13b of the amplifier 13, and a second end 221b of the input-side coil 221 is connected to the output terminal 12b of the amplifier 12 via the transmission line 31.

The output-side coil 222 is an example of a second output-side coil. A first end 222a of the output-side coil 222 is connected to the output terminal 102 of the amplifier circuit 10, and a second end 222b of the output-side coil 222 is connected to the ground.

The transmission line 31 is a ¼ wavelength transmission line and may also be referred to as a phase adjuster or a phase shifter. The ¼ wavelength of the transmission line 31 is determined based on the bands A and B. The transmission line 31 is connected between the output terminal 12b of the amplifier 12 and each of the second end 211b of the input-side coil 211 of the transformer 21 and the second end 221b of the input-side coil 221 of the transformer 22. The transmission line 31 shifts the phases of signals in the bands A and B output from the amplifier 12 by −90 degrees (or delays the phases by 90 degrees).

The output terminal 101 is an example of a first output terminal and is used to supply transmission signals in the band A. Transmission signals in the band A amplified by the amplifiers 11 and 12 are output via the output terminal 101.

The output terminal 102 is an example of a second output terminal and is used to supply transmission signals in the band B. Transmission signals in the band B amplified by the amplifiers 12 and 13 are output via the output terminal 102.

The configuration of the amplifier circuit 10 is not limited to the example illustrated in FIG. 1. As another example, the amplifier circuit 10 may include the input network 41.

### [1.1.4 Circuit Configurations of Amplifiers 11 Through 13]

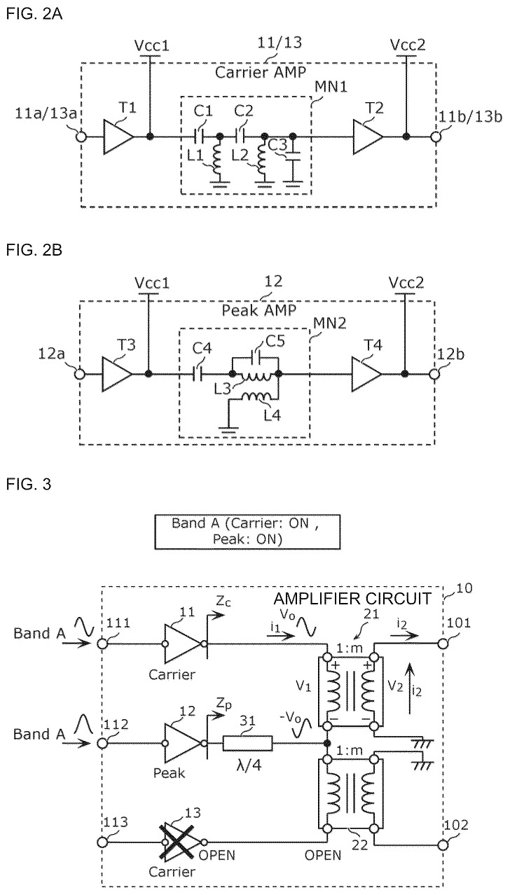

Next, circuit configurations of a carrier amplifier (the amplifier 11 or 13) and a peak amplifier (the amplifier 12) included in the amplifier circuit 10 are described with reference to FIGS. 2A and 2B. FIG. 2A is a circuit diagram of the carrier amplifier according to the present embodiment. FIG. 2B is a circuit diagram of the peak amplifier according to the present embodiment.

First, the carrier amplifier (the amplifier 11) is described with reference to FIG. 2A. The amplifier 13 has substantially the same configuration as the amplifier 11, and therefore descriptions of the amplifier 13 are omitted. The carrier amplifier includes amplifying elements T1 and T2 and a matching circuit MN1.

The amplifying element T1 corresponds to an input stage of a multi-stage amplifier. An input end of the amplifying element T1 is connected to the input terminal 11a, and an output end of the amplifying element T1 is connected to the matching circuit MN1. With this connection configuration and with a power supply voltage Vcc1 applied, the amplifying element T1 can amplify a signal received by the input terminal 11a.

The matching circuit MN1 is connected between the amplifying elements T1 and T2 and can provide impedance matching between the amplifying elements T1 and T2. Specifically, the matching circuit MN1 includes capacitors C1, C2, and C3 and inductors L1 and L2.

The capacitors C1 and C2 are series arm elements connected to a path connecting the amplifying elements T1 and T2 to each other and function as so-called series capacitors. On the other hand, the capacitor C3 and the inductors L1 and L2 are parallel arm elements connected between the ground and the path connecting the amplifying element T1 to the amplifying element T2 and function as a so-called shunt capacitor and so-called shunt inductors, respectively.

The amplifying element T2 corresponds to an output stage of a multi-stage amplifier. An input end of the amplifying element T2 is connected to the matching circuit MN1, and an output end of the amplifying element T2 is connected to the output terminal 11b. With this connection configuration and with a power supply voltage Vcc2 applied, the amplifying element T2 can further amplify the signal amplified by the amplifying element T1.

Each of the amplifying elements T1 and T2 may be implemented by a bipolar transistor, such as a heterojunction bipolar transistor (HBT), or a field-effect transistor (FET), such as a metal-oxide-semiconductor field effect transistor (MOSFET).

Next, the peak amplifier (the amplifier 12) is described with reference to FIG. 2B. The peak amplifier includes amplifying elements T3 and T4 and a matching circuit MN2.

The amplifying element T3 corresponds to an input stage of a multi-stage amplifier. An input end of the amplifying element T3 is connected to the input terminal 12a, and an output end of the amplifying element T3 is connected to the matching circuit MN2. With this connection configuration and with the power supply voltage Vcc1 applied, the amplifying element T3 can amplify a signal received by the input terminal 12a.

The matching circuit MN2 is connected between the amplifying elements T3 and T4 and can provide impedance matching between the amplifying elements T3 and T4. Specifically, the matching circuit MN2 includes capacitors C4 and C5 and coils L3 and L4.

The coils L3 and L4 are connected to each other and constitute an autotransformer. One end of the capacitor C4 is connected to the output end of the amplifying element T3, and another end of the capacitor C4 is connected to a first end of the coil L3. One end of the capacitor C5 is connected to the first end of the coil L3, and another end of the capacitor C5 is connected to a second end of the coil L3. With this configuration, the matching circuit MN2 can provide impedance matching in a wider band compared to the matching circuit MN1.

The amplifying element T4 corresponds to an output stage of a multi-stage amplifier. An input end of the amplifying element T4 is connected to the matching circuit MN2, and an output end of the amplifying element T4 is connected to the output terminal 12b. With connection configuration and with the power supply voltage Vcc2 applied, the amplifying element T4 can further amplify the signal amplified by the amplifying element T3.

Similarly to the amplifying elements T1 and T2, each of the amplifying elements T3 and T4 may be implemented by a bipolar transistor, such as a heterojunction bipolar transistor (HBT), or a field-effect transistor (FET), such as a metal-oxide-semiconductor field effect transistor (MOSFET).

The configurations of the amplifiers 11 through 13 are not limited to the configurations illustrated in FIGS. 2A and 2B. For example, the amplifiers 11 through 13 may share an amplifying element for the input stage. For example, the amplifying element for the input stage may be connected between the radio frequency input terminal 110 and the input network 41. In this case, the amplifying element T1 of the carrier amplifier and the amplifying element T3 of the peak amplifier may be omitted. Also, each of the amplifiers 11 through 13 does not necessarily include an amplifying element for an input stage. Furthermore, each of the amplifiers 11 through 13 may include a matching circuit different from the matching circuit MN1/MN2 instead of or in addition to the matching circuit MN1/MN2.

### [1.2 Operations of Amplifier Circuit 10]

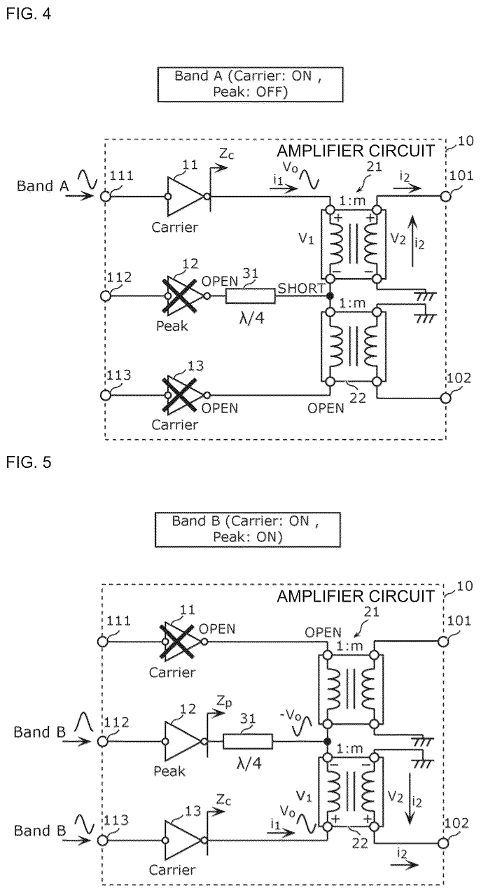

Next, operations of the amplifier circuit 10 according to the present embodiment are described. First, operations performed based on a signal in the band A being input are described with reference to FIGS. 3 and 4.

FIG. 3 is a circuit state diagram of the amplifier circuit 10 according to the present embodiment based on a large signal (e.g., relative to a power threshold) in the band A being input. FIG. 4 is a circuit state diagram of the amplifier circuit 10 according to the present embodiment based on a small signal (e.g., relative to a power threshold) in the band A being input.

As illustrated in FIG. 3, based on the power of an input signal in the band A being high (e.g., relative to a power threshold), the amplifiers 11 and 12 operate (ON), and the amplifier 13 does not operate (OFF). In this case, output impedance Z_{c} seen from the output terminal 11b of the amplifier 11 toward the load and output impedance Zₚ seen from the output terminal 12b of the amplifier 12 toward the load are represented by Formula 1 below.

$$[ Math . 1 ]$$

$${V}_{2} = {mV}_{1} = 2 {mV}_{o} \\ {i}_{2} = \frac{1}{m} {i}_{1} \\ {R}_{L} = \frac{{V}_{2}}{{i}_{2}} = \frac{2 {mV}_{o}}{\frac{1}{m} {i}_{1}} = \frac{2 {m}^{2} {V}_{o}}{{i}_{1}} \\ {Z}_{c} = {Z}_{p} = \frac{{V}_{o}}{{i}_{1}} = {V}_{o} \times \frac{{R}_{L}}{2 {m}^{2} {V}_{o}} = \frac{{R}_{L}}{2 {m}^{2}} \qquad ( Formula 1 )$$

Here, the transformation ratio of the transformer 21 is represented by 1:m. V₁ represents a voltage applied between the ends of the input-side coil 211 of the transformer 21. V₂ represents a voltage applied between the ends of the output-side coil 212 of the transformer 21. Also, i₁ represents an electric current that flows through the input-side coil 211 of the transformer 21. Furthermore, i₂ represents an electric current that flows through the output-side coil 212 of the transformer 21. Vₒ represents an output voltage of each of the amplifiers 11 and 12. R_{L} represents the impedance of a load connected to the output terminal 101. Here, output impedance seen from the output terminal 13b of the amplifier 13 toward the load is in an open state.

As illustrated in FIG. 4, based on the power of an input signal in the band A being low (e.g., relative to a power threshold), the amplifier 11 operates (ON), and the amplifiers 12 and 13 do not operate (OFF). In this case, output impedance Z_{c} seen from the output terminal 11b of the amplifier 11 toward the load is expressed by Formula 2 below.

$$[ Math . 2 ]$$

$${V}_{2} = {mV}_{1} = {mV}_{o} \\ {i}_{2} = \frac{1}{m} {i}_{1} \\ {R}_{L} = \frac{{V}_{2}}{{i}_{2}} = \frac{{mV}_{o}}{\frac{1}{m} {i}_{1}} = \frac{{m}^{2} {V}_{o}}{{i}_{1}} \\ {Z}_{c} = \frac{{V}_{o}}{{i}_{1}} = {V}_{o} \times \frac{{R}_{L}}{{m}^{2} {V}_{o}} = \frac{{R}_{L}}{{m}^{2}} \qquad ( Formula 2 )$$

Here, the transformation ratio of the transformer 21 is represented by 1:m. V₁ represents a voltage applied between the ends of the input-side coil 211 of the transformer 21. V₂ represents a voltage applied between the ends of the output-side coil 212 of the transformer 21. Also, i₁ represents an electric current that flows through the input-side coil 211 of the transformer 21. Furthermore, i₂ represents an electric current that flows through the output-side coil 212 of the transformer 21. Vₒ represents an output voltage of the amplifier 11. R_{L} represents the impedance of a load connected to the output terminal 101. Here, each of output impedance seen from the output terminal 12b of the amplifier 12 toward the load and output impedance seen from the output terminal 13b of the amplifier 13 toward the load is in an open state.

As is apparent from Formula 1 and Formula 2, based on a small signal in the band A being input, the amplifier 11 goes into the ON state and the amplifier 12 goes into the OFF state. As a result, the output impedance Z_{c} of the amplifier 11 becomes higher (two times greater) than that observed based on a large signal being input. This in turn enables the amplifier circuit 10 to operate with high efficiency.

In contrast, based on a large signal in the band A being input, both of the amplifiers 11 and 12 go into the ON state. This enables the amplifier circuit 10 to output a high power signal. Also, because the output impedance Z_{c} of the amplifier 11 becomes lower than (becomes one-half of) that observed based on a small signal being input, the amplifier circuit 10 can suppress signal distortion.

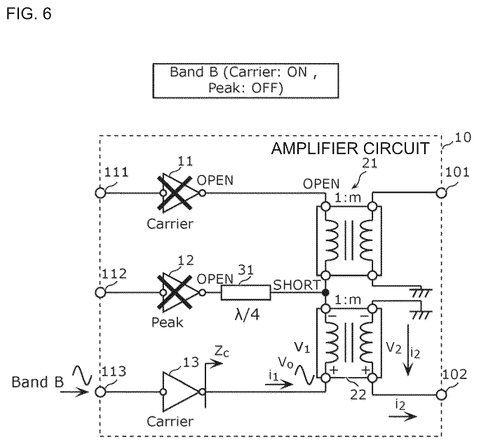

Next, operations performed based on signals in the band B being input are described with reference to FIGS. 5 and 6.

As illustrated in FIG. 5, based on the power of an input signal in the band B being high (e.g., relative to a power threshold), the amplifiers 12 and 13 operate (ON), and the amplifier 11 does not operate (OFF). In this case, the output impedance Z_{c} seen from the output terminal 13b of the amplifier 13 toward the load and the output impedance Zₚ seen from the output terminal 12b of the amplifier 12 toward the load are expressed by Formula 3 below.

$$[ Math . 3 ]$$

$${V}_{2} = {mV}_{1} = 2 {mV}_{o} \\ {i}_{2} = \frac{1}{m} {i}_{1} \\ {R}_{L} = \frac{{V}_{2}}{{i}_{2}} = \frac{2 {mV}_{o}}{\frac{1}{m} {i}_{1}} = \frac{2 {m}^{2} {V}_{o}}{{i}_{1}} \\ {Z}_{c} = {Z}_{p} = \frac{{V}_{o}}{{i}_{1}} = {V}_{o} \times \frac{{R}_{L}}{2 {m}^{2} {V}_{o}} = \frac{{R}_{L}}{2 {m}^{2}} \qquad ( Formula 3 )$$

Here, the transformation ratio of the transformer 22 is represented by 1:m. V₁ represents a voltage applied between the ends of the input-side coil 221 of the transformer 22. V₂ represents a voltage applied between the ends of the output-side coil 222 of the transformer 22. Also, i₁ represents an electric current that flows through the input-side coil 221 of the transformer 22. Furthermore, i₂ represents an electric current that flows through the output-side coil 222 of the transformer 22. Vₒ represents an output voltage of each of the amplifiers 12 and 13. R_{L} represents the impedance of a load connected to the output terminal 102. Here, output impedance seen from the output terminal 11b of the amplifier 11 toward the load is in an open state.

As illustrated in FIG. 6, based on the power of an input signal in the band B being low, the amplifier 13 operates (ON) and the amplifiers 11 and 12 do not operate (OFF). In this case, the output impedance Z_{c} seen from the output terminal 13b of the amplifier 13 toward the load is represented by Formula 4 below.

$$[ Math . 4 ]$$

$${V}_{2} = {mV}_{1} = {mV}_{o} \\ {i}_{2} = \frac{1}{m} {i}_{1} \\ {R}_{L} = \frac{{V}_{2}}{{i}_{2}} = \frac{{mV}_{o}}{\frac{1}{m} {i}_{1}} = \frac{{m}^{2} {V}_{o}}{{i}_{1}} \\ {Z}_{c} = \frac{{V}_{o}}{{i}_{1}} = {V}_{o} \times \frac{{R}_{L}}{{m}^{2} {V}_{o}} = \frac{{R}_{L}}{{m}^{2}} \qquad ( Formula 4 )$$

Here, the transformation ratio of the transformer 22 is represented by 1:m. V₁ represents a voltage applied between the ends of the input-side coil 221 of the transformer 22. V₂ represents a voltage applied between the ends of the output-side coil 222 of the transformer 22. Also, i₁ represents an electric current that flows through the input-side coil 221 of the transformer 22. Furthermore, i₂ represents an electric current that flows through the output-side coil 222 of the transformer 22. Vₒ represents an output voltage of the amplifier 13. R_{L} represents the impedance of a load connected to the output terminal 102. Here, each of output impedance seen from the output terminal 11b of the amplifier 11 toward the load and output impedance seen from the output terminal 12b of the amplifier 12 toward the load is in an open state.

As is apparent from Formula 3 and Formula 4, based on a small signal in the band B being input, the amplifier 13 goes into the ON state, and the amplifier 12 goes into the OFF state. As a result, the output impedance Z_{c} of the amplifier 13 becomes higher (two times greater) than that observed based on a large signal being input. This in turn enables the amplifier circuit 10 to operate with high efficiency.

In contrast, based on a large signal in the band B being input, both of the amplifiers 12 and 13 go into the ON state. As a result, the amplifier circuit 10 can output a high power signal. Also, because the output impedance Z_{c} of the amplifier 13 becomes lower than (becomes one-half of) that observed based on a small signal being input, the amplifier circuit 10 can suppress signal distortion.

As described above, in the amplifier circuit 10, the amplifier 11 functions as a carrier amplifier for the band A, and the amplifier 13 functions as a carrier amplifier for the band B. On the other hand, the amplifier 12 functions as a peak amplifier for the bands A and B. That is, in the amplifier circuit 10, a dedicated carrier amplifier is provided for each of the bands A and B, and a common peak amplifier is provided for the bands A and B.

### [1.3 Layout of Components of Amplifier Circuit 10]

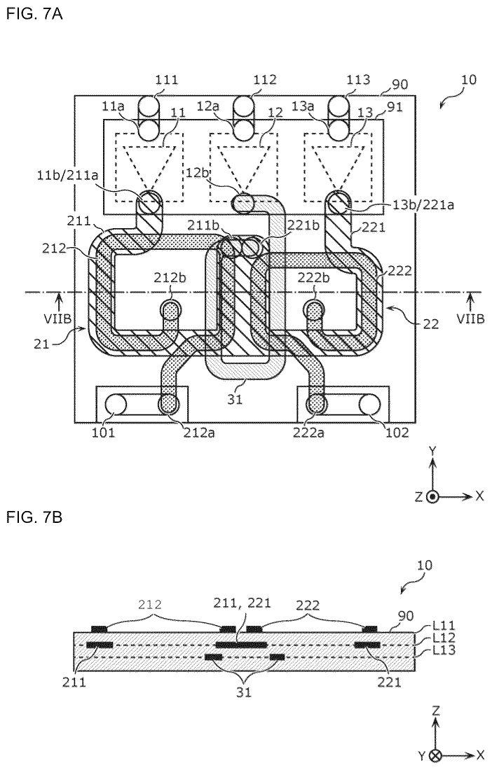

Next, an example of a layout of components of the amplifier circuit 10 according to the present embodiment is described with reference to FIGS. 7A and 7B. FIG. 7A is a plan view of the amplifier circuit 10 according to the present embodiment. FIG. 7B is a cross-sectional view of the amplifier circuit 10 according to the present embodiment.

Specifically, FIG. 7A is a transparent view of a layout of circuit components based on a major surface of a substrate 90 being seen from the positive z-axis direction, and FIG. 7B is a cross-sectional view taken along line VIIB-VIIB of FIG. 7A. Circuit components in FIG. 7A may be provided with symbols representing their functions to facilitate the understanding of the layout of the circuit components. However, such symbols are not provided on the actual circuit components. Also, in FIGS. 7A and 7B, the illustration of wires connecting the substrate 90 to the circuit components may be omitted.

The amplifier circuit 10 may further include a resin component covering the surfaces of the substrate 90 and the circuit components and a shield electrode layer covering the surface of the resin component. However, the resin component and the shield electrode layer are omitted in FIGS. 7A and 7B.

Circuit components constituting the amplifier circuit 10 are mounted on or in the substrate 90. The substrate 90 is implemented by, for example, a low-temperature co-fired ceramics (LTCC) substrate with a multilayer structure formed of multiple dielectric layers, a high-temperature co-fired ceramics (HTCC) substrate, a component built-in substrate, a substrate including a redistribution layer (RDL), or a printed-circuit board.

The amplifiers 11 through 13 are included in a semiconductor IC 91 disposed on or in the substrate 90. In plan view of the semiconductor IC 91, the amplifier 12 is disposed between the amplifiers 11 and 13. In FIG. 7A, the amplifiers 11 through 13 are arranged in this order along the X direction, and the output terminals 11b through 13b of the amplifiers 11 through 13 are also arranged in the same order along the X direction.

The semiconductor IC 91 is an example of an integrated circuit and is implemented by using, for example, a complementary metal oxide semiconductor (CMOS). Specifically, the semiconductor IC 91 may be manufactured by a Silicon on Insulator (SOI) process. Also, the semiconductor IC 91 may be comprised of at least one of GaAs, SiGe, and GaN. However, semiconductor materials of the semiconductor IC 91 are not limited to those described above.

The transformers 21 and 22 are formed on the surface of and inside of the substrate 90. In FIGS. 7A and 7B, the output-side coils 212 and 222 of the transformers 21 and 22 are formed on a first layer L11 of the substrate 90 as planar conductors. Also, the input-side coils 211 and 221 of the transformers 21 and 22 are formed in a second layer L12 of the substrate 90 as planar conductors. In plan view of the substrate 90, at least a part of the input-side coil 211 overlaps at least a part of the output-side coil 212, and at least a part of the input-side coil 221 overlaps at least a part of the output-side coil 222.

The transmission line 31 is formed inside of the substrate 90. In FIGS. 7A and 7B, the transmission line 31 is formed in a third layer L13 of the substrate 90 as a planar conductor.

The layout of components of the amplifier circuit 10 is not limited to the example illustrated in FIGS. 7A and 7B. As another example, the output-side coils 212 and 222 may be formed inside of the substrate 90, and the input-side coils 211 and 221 may be formed on the surface of the substrate 90. Also, the output-side coils 212 and 222 may be formed in different layers, and the input-side coils 211 and 221 may be formed in different layers. Furthermore, each of the input-side coils 211 and 221, the output-side coils 212 and 222, and the transmission line 31 may be formed across multiple layers.

In addition, any other circuit component included in the radio frequency circuit 1 may also be disposed on or in the substrate 90. Specifically, at least one of the input network 41, the filters 61 and 62, and the switch 51 may be disposed on or in the substrate 90.

### [1.4 Effects]

As described above, the amplifier circuit 10 according to the present embodiment includes the output terminals 101 and 102, the amplifiers 11 through 13, the transformer 21 including the input-side coil 211 and the output-side coil 212, the transformer 22 including the input-side coil 221 and the output-side coil 222, and the transmission line 31 connected to the output terminal 12b of the amplifier 12. The first end 211a of the input-side coil 211 is connected to the output terminal 11b of the amplifier 11, the second end 211b of the input-side coil 211 is connected to the output terminal 12b of the amplifier 12 via the transmission line 31, the first end 221a of the input-side coil 221 is connected to the output terminal 13b of the amplifier 13, the second end 221b of the input-side coil 221 is connected to the output terminal 12b of the amplifier 12 via the transmission line 31, the first end 212a of the output-side coil 212 is connected to the output terminal 101, the second end 212b of the output-side coil 212 is connected to the ground, the first end 222a of the output-side coil 222 is connected to the output terminal 102, and the second end 222b of the output-side coil 222 is connected to the ground.

With this configuration, transmission signals in different bands can be amplified by a combination of the amplifiers 11 and 12 and a combination of the amplifiers 12 and 13, and the amplifier circuit 10 can be used as a Doherty amplifier circuit that supports two bands. In this configuration, based on the amplifier 11 being used for one of the two bands and the amplifier 13 is used for the other one of the two bands, the amplifier 12 can be used for both of the two bands. Accordingly, compared with a configuration in which two amplifiers are used for each of two bands (i.e., based on the amplifier 12 being implemented by two amplifiers), the above configuration makes it possible to reduce the number of amplifiers included in the amplifier circuit 10. Furthermore, compared with a configuration in which each of two amplifiers is used for two bands (i.e., based on the amplifiers 11 and 13 being implemented by one amplifier), the above configuration makes it possible to use the amplifiers 11 and 13 each of which has amplification characteristics suitable for the corresponding one of the two bands. In other words, the amplifier circuit 10 according to the present embodiment can be used as a Doherty amplifier circuit and can suppress the increase in the number of amplifiers while reducing the deterioration of amplification characteristics in multiband applications.

For example, in the amplifier circuit 10 according to the present embodiment, each of the amplifiers 11 and 13 may be a carrier amplifier, and the amplifier 12 may be a peak amplifier.

With this configuration, the amplifier circuit 10 can have two carrier amplifiers each of which supports one of two bands and one peak amplifier that supports the two bands. This in turn makes it possible to use separate carrier amplifiers, each of which operates with either one of a large signal and a small signal (e.g., relative to a power threshold), for two bands and use one peak amplifier, which operates only with a large signal, for the two bands. Compared with a case in which one carrier amplifier is used for the two bands, this configuration makes it possible to reduce the deterioration of amplification characteristics.

For example, in the amplifier circuit 10 according to the present embodiment, the amplifier 11 may be capable of amplifying a signal in the band A, the amplifier 13 may be capable of amplifying a signal in the band B, and the amplifier 12 may be capable of amplifying a signal in the band A and a signal in the band B.

This configuration makes it possible to use the amplifier 11 for the band A, the amplifier 13 for the band B, and the amplifier 12 for the bands A and B.

For example, in the amplifier circuit 10 according to the present embodiment, signals in the band A amplified by the amplifiers 11 and 12 may be output via the output terminal 101, and signals in the band B amplified by the amplifiers 12 and 13 may be output via the output terminal 102.

This configuration makes it possible to output a signal in the band A and a signal in the band B from different output terminals and to omit a switch for switching between the bands A and B.

For example, in the amplifier circuit 10 according to the present embodiment, the amplifiers 11 through 13 may be included in one semiconductor IC 91; and in plan view of the semiconductor IC 91, the amplifier 12 may be disposed between the amplifiers 11 and 13.

This configuration makes it possible to implement the amplifiers 11 through 13 with one semiconductor IC 91 and thereby makes it possible to reduce the size of the amplifier circuit 10. Furthermore, disposing the amplifier 12 between the amplifiers 11 and 13 makes it possible to reduce the lengths of wires that connect the amplifiers 11 through 13 to the output terminals 101 and 102. This in turn makes it possible to reduce wire loss and mismatching loss caused by stray capacitance of wires and thereby makes it possible to improve the characteristics of the amplifier circuit 10.

Also, the radio frequency circuit 1 according to the present embodiment includes the amplifier circuit 10, the filter 61 that is connected to the output terminal 101 and has a pass band including the band A, and the filter 62 that is connected to the output terminal 102 and has a pass band including the band B.

This makes it possible to provide the radio frequency circuit 1 having the effects of the amplifier circuit 10 described above.

### First Variation of First Embodiment

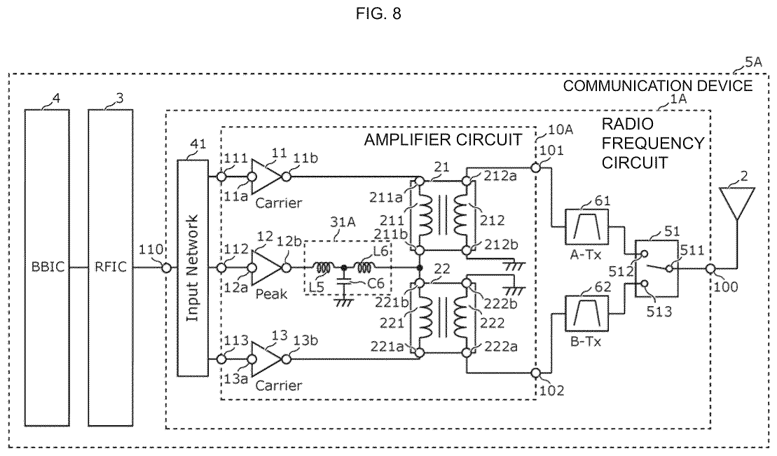

Next, a first variation of the first embodiment is described. The first variation mainly differs from the first embodiment in the configuration of a transmission line. Below, differences between the first variation and the first embodiment are mainly described with reference to FIG. 8.

FIG. 8 is a circuit diagram of an amplifier circuit 10A, a radio frequency circuit 1A, and a communication device 5A according to this variation. The communication device 5A differs from the communication device 5 of the first embodiment in that the radio frequency circuit 1A is provided in place of the radio frequency circuit 1. The radio frequency circuit 1A differs from the radio frequency circuit 1 of the first embodiment in that the amplifier circuit 10A is provided in place of the amplifier circuit 10. The amplifier circuit 10A differs from the amplifier circuit 10 of the first embodiment in that a transmission line 31A is provided in place of the transmission line 31.

The transmission line 31A may also be referred to as a phase adjuster or a phase shifter. The transmission line 31A is connected between the output terminal 12b of the amplifier 12 and each of the second end 211b of the input-side coil 211 of the transformer 21 and the second end 221b of the input-side coil 221 of the transformer 22.

As illustrated in FIG. 8, the transmission line 31A includes inductors L5 and L6 and a capacitor C6. The inductors L5 and L6 are series arm elements connected to a path that connects the output terminal 12b of the amplifier 12 to the second end 211b of the input-side coil 211 of the transformer 21 and the second end 221b of the input-side coil 221 of the transformer 22, and function as so-called series inductors. On the other hand, the capacitor C6 is a parallel arm element connected between the ground and the path connecting the output terminal 12b of the amplifier 12 to the second end 211b of the input-side coil 211 of the transformer 21 and the second end 221b of the input-side coil 221 of the transformer 22, and functions as a so-called shunt capacitor. With this configuration, the transmission line 31A is capable of shifting the phases of signals in the bands A and B output from the amplifier 12 by −90 degrees (or delaying the phases by 90 degrees).

The internal configuration of the transmission line 31A is not limited to the example illustrated in in FIG. 8. As another example, the capacitor C6 may be a series arm element, and the inductor L5 and/or the inductor L6 may be a parallel arm element. Also, the transmission line 31A may be configured to include only one of an inductor and a capacitor. That is, the transmission line 31A may include at least one of an inductor and a capacitor.

As described above, in the amplifier circuit 10A according to this variation, the transmission line 31A includes at least one of an inductor and a capacitor.

This configuration makes it possible use an inductor and/or a capacitor for the transmission line 31A and thereby makes it possible to reduce the length of the transmission line 31A.

### Second Variation of First Embodiment

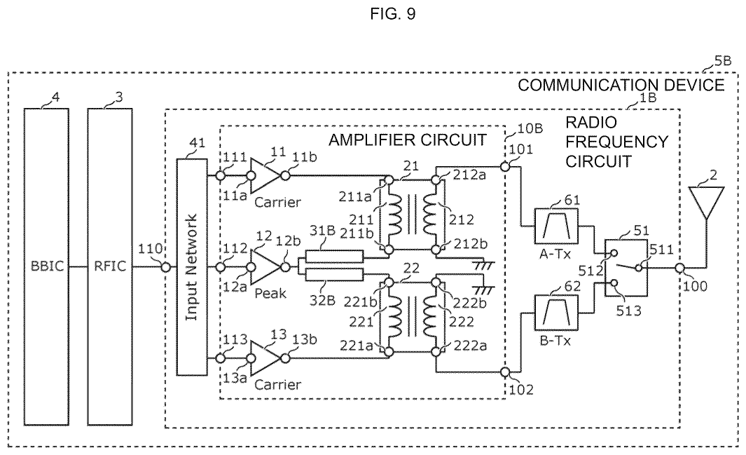

Next, a second variation of the first embodiment is described. This variation mainly differs from the first embodiment in the configuration of a transmission line. Below, differences between the second variation and the first embodiment are mainly described with reference to FIG. 9.

FIG. 9 is a circuit diagram of an amplifier circuit 10B, a radio frequency circuit 1B, and a communication device 5B according to this variation. The communication device 5B differs from the communication device 5 of the first embodiment in that a radio frequency circuit 1B is provided in place of the radio frequency circuit 1. The radio frequency circuit 1B differs from the radio frequency circuit 1 of the first embodiment in that the amplifier circuit 10B is provided in place of the amplifier circuit 10. The amplifier circuit 10B differs from the amplifier circuit 10 of the first embodiment in that transmission lines 31B and 32B are provided in place of the transmission line 31.

The transmission line 31B is an example of a first transmission line and is a ¼ wavelength transmission line. In this variation, the ¼ wavelength of the transmission line 31B is determined based on the band A. The transmission line 31B is connected between the output terminal 12b of the amplifier 12 and the second end 211b of the input-side coil 211 of the transformer 21. The transmission line 31B shifts the phase of a signal in the band A output from the amplifier 12 by −90 degrees (or delays the phase by 90 degrees).

The transmission line 32B is an example of a second transmission line and is a ¼ wavelength transmission line. In this variation, the ¼ wavelength of the transmission line 32B is determined based on the band B. The transmission line 32B is connected between the output terminal 12b of the amplifier 12 and the second end 221b of the input-side coil 221 of the transformer 22. The transmission line 32B shifts the phase of a signal in the band B output from the amplifier 12 by −90 degrees (or delays the phase by 90 degrees).

As described above, the amplifier circuit 10B of this variation includes the transmission line 31B connected between the output terminal 12b of the amplifier 12 and the second end 211b of the input-side coil 211 and the transmission line 32B connected between the output terminal 12b of the amplifier 12 and the second end 221b of the input-side coil 221.

This configuration makes it possible to use the transmission lines 31B and 32B each of which is suitable for the corresponding one of the two bands. That is, it is possible to use a ¼ wavelength transmission line corresponding to the band A as the transmission line 31B and use a ¼ wavelength transmission line corresponding to the band B as the transmission line 32B. This in turn makes it possible to ensure that the transmission lines 31B and 32B are short-circuited on the transformer side based on the amplifier 12 not operating.

### Second Embodiment

Next, a second embodiment is described with reference to the drawings. The second embodiment mainly differs from the first embodiment in the configurations of transformers and transmission lines. Below, differences between this embodiment and the first embodiment are mainly described.

### [2.1 Circuit Configurations of Communication Device 5C, Radio Frequency Circuit 1C, and Amplifier Circuit 10C]

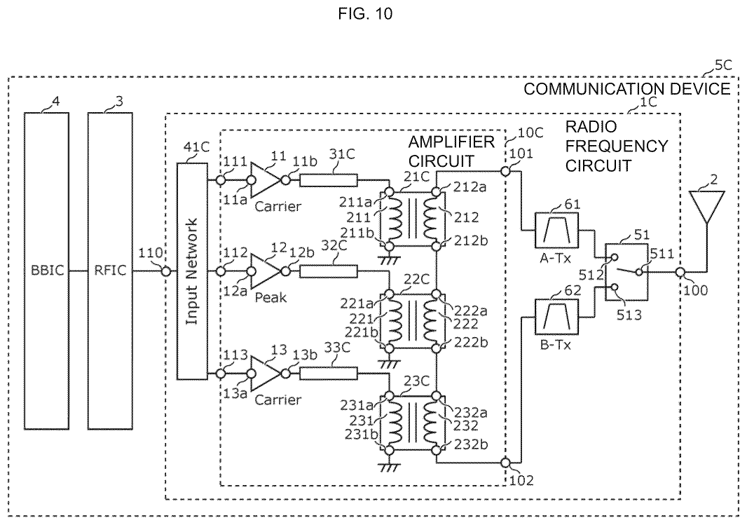

Circuit configurations of a communication device 5C, a radio frequency circuit 1C, and an amplifier circuit 10C according to the present embodiment are described below with reference to FIG. 10. FIG. 10 is a circuit diagram of the amplifier circuit 10C, the radio frequency circuit 1C, and the communication device 5C according to the present embodiment.

The communication device 5C differs from the communication device 5 of the first embodiment in that the radio frequency circuit 1C is provided in place of the radio frequency circuit 1. The radio frequency circuit 1C differs from the radio frequency circuit 1 of the first embodiment in that the amplifier circuit 10C and an input network 41C are provided in place of the amplifier circuit 10 and the input network 41.

The input network 41C splits an input signal received via the radio frequency input terminal 110 and outputs split signals obtained by splitting the input signal to the amplifier circuit 10C. In the present embodiment, the input network 41C is not necessarily configured to adjust the phases of the split signals.

### [2.1.1 Circuit Configuration of Amplifier Circuit 10C]

Here, a circuit configuration of the amplifier circuit 10C is described. As illustrated in FIG. 10, the amplifier circuit 10C includes amplifiers 11 through 13, transformers 21C through 23C, transmission lines 31C through 33C, input terminals 111 through 113, and output terminals 101 and 102.

The transformer 21C is an example of a first transformer. The transformer 21C includes an input-side coil 211 and an output-side coil 212.

The input-side coil 211 is an example of a first input-side coil. A first end 211a of the input-side coil 211 is connected to the output terminal 11b of the amplifier 11 via the transmission line 31C, and a second end 211b of the input-side coil 211 is connected to the ground.

The output-side coil 212 is an example of a first output-side coil. A first end 212a of the output-side coil 212 is connected to the output terminal 101 of the amplifier circuit 10C, and a second end 212b of the output-side coil 212 is connected to the transformer 22C.

The transformer 22C is an example of a second transformer. The transformer 22C includes an input-side coil 221 and an output-side coil 222.

The input-side coil 221 is an example of a second input-side coil. A first end 221a of the input-side coil 221 is connected to the output terminal 12b of the amplifier 12 via the transmission line 32C, and the second end 221b of the input-side coil 221 is connected to the ground.

The output-side coil 222 is an example of a second output-side coil. A first end 222a of the output-side coil 222 is connected to the second end 212b of the output-side coil 212 of the transformer 21C, and a second end 222b of the output-side coil 222 is connected to the transformer 23C.

The transformer 23C is an example of a third transformer. The transformer 23C includes an input-side coil 231 and an output-side coil 232.

The input-side coil 231 is an example of a third input-side coil. A first end 231a of the input-side coil 231 is connected to the output terminal 13b of the amplifier 13 via the transmission line 33C, and a second end 231b of the input-side coil 231 is connected to the ground.

The output-side coil 232 is an example of a third output-side coil. A first end 232a of the output-side coil 232 is connected to the second end 222b of the output-side coil 222 of the transformer 22C, and a second end 232b of the output-side coil 232 is connected to the output terminal 102 of the amplifier circuit 10C.

The transmission line 31C is an example of a first transmission line and is a ¼ wavelength transmission line. The transmission line 31C may also be referred to as a phase adjuster or a phase shifter. The ¼ wavelength of the transmission line 31C is determined based on the band A. The transmission line 31C is connected between the output terminal 11b of the amplifier 11 and the first end 211a of the input-side coil 211 of the transformer 21C. The transmission line 31C shifts the phase of a signal in the band A output from the amplifier 11 by −90 degrees (or delays the phase by 90 degrees).

The transmission line 32C is an example of a second transmission line and is a ¼ wavelength transmission line. The transmission line 32C may also be referred to as a phase adjuster or a phase shifter. The ¼ wavelength of the transmission line 32C is determined based on the bands A and B. The transmission line 32C is connected between the output terminal 12b of the amplifier 12 and the first end 221a of the input-side coil 221 of the transformer 22C. The transmission line 32C shifts the phases of signals in the bands A and B output from the amplifier 12 by −90 degrees (or delays the phases by 90 degrees).

The transmission line 33C is an example of a third transmission line and is a ¼ wavelength transmission line. The transmission line 33C may also be referred to as a phase adjuster or a phase shifter. The ¼ wavelength of the transmission line 33C is determined based on the band B. The transmission line 33C is connected between the output terminal 13b of the amplifier 13 and the first end 231a of the input-side coil 231 of the transformer 23C. The transmission line 33C shifts the phase of a signal in the band B output from the amplifier 13 by −90 degrees (or delays the phase by 90 degrees).

### [2.2 Operations of Amplifier Circuit 10C]

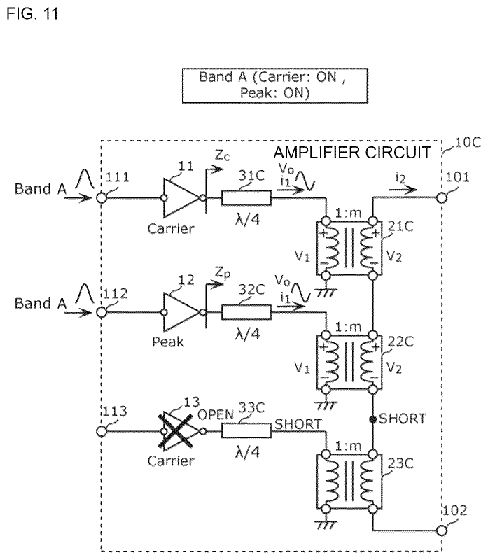

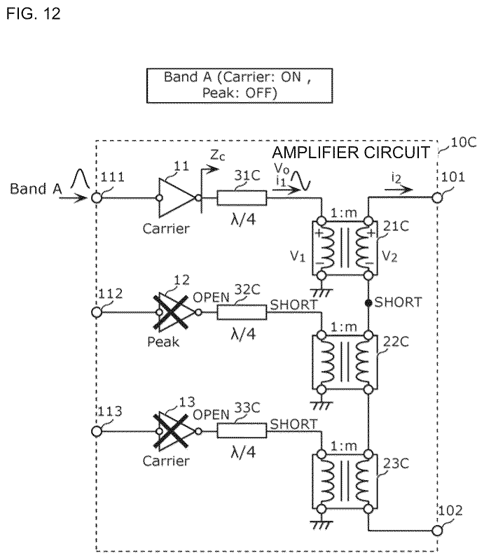

Next, operations of the amplifier circuit 10C according to the present embodiment are described. First, operations performed based on a signal in the band A being input are described with reference to FIGS. 11 and 12.

FIG. 11 is a circuit state diagram of the amplifier circuit 10C according to the present embodiment based on a large signal (e.g., relative to a power threshold) in the band A being input. FIG. 12 is a circuit state diagram of the amplifier circuit 10C according to the present embodiment based on a small signal (e.g., relative to a power threshold) in the band A being input.

As illustrated in FIG. 11, based on the power of an input signal in the band A being high (e.g., relative to a power threshold), the amplifiers 11 and 12 operate (ON), and the amplifier 13 does not operate (OFF). In this case, output impedance Z_{c} seen from the output terminal 11b of the amplifier 11 toward the load and output impedance Zₚ seen from the output terminal 12b of the amplifier 12 toward the load are represented by Formula 5 below.

$$[ Math . 5 ]$$

$${V}_{2} = {mV}_{1} = {mV}_{o} \\ {i}_{2} = \frac{1}{m} {i}_{1} \\ {R}_{L} = \frac{{V}_{2} + {V}_{2}}{{i}_{2}} = \frac{{mV}_{o} + {mV}_{o}}{\frac{1}{m} {i}_{1}} = \frac{2 {m}^{2} {V}_{o}}{{i}_{1}} \\ {Z}_{c} = {Z}_{p} = \frac{{V}_{o}}{{i}_{1}} = {V}_{o} \times \frac{{R}_{L}}{2 {m}^{2} {V}_{o}} = \frac{{R}_{L}}{2 {m}^{2}} \qquad ( Formula 5 )$$

Here, the transformation ratio of each of the transformers 21C and 22C is represented by 1:m. V₁ represents a voltage applied between the ends of the input-side coil 211 of the transformer 21C and a voltage applied between the ends of the input-side coil 221 of the transformer 22C. V₂ represents a voltage applied between the ends of the output-side coil 212 of the transformer 21C and a voltage applied between the ends of the output-side coil 222 of the transformer 22C. Also, i₁ represents an electric current that flows through the input-side coil 211 of the transformer 21C and an electric current that flows through the input-side coil 221 of the transformer 22C. Furthermore, i₂ represents an electric current that flows through the output-side coil 212 of the transformer 21C and an electric current that flows through the output-side coil 222 of the transformer 22C. Vₒ represents an output voltage of each of the amplifiers 11 and 12. R_{L} represents impedance of a load connected to the output terminal 101. Here, output impedance seen from the output terminal 13b of the amplifier 13 toward the load is in an open state.

As illustrated in FIG. 12, based on the power of an input signal in the band A being low, the amplifier 11 operates (ON), and the amplifiers 12 and 13 do not operate (OFF). In this case, output impedance Z_{c} seen from the output terminal 11b of the amplifier 11 toward the load is expressed by Formula 6 below.

$$[ Math . 6 ]$$

$${V}_{2} = {mV}_{1} = {mV}_{o} \\ {i}_{2} = \frac{1}{m} {i}_{1} \\ {R}_{L} = \frac{{V}_{2}}{{i}_{2}} = \frac{{mV}_{o}}{\frac{1}{m} {i}_{1}} = \frac{{m}^{2} {V}_{o}}{{i}_{1}} \\ {Z}_{c} = \frac{{V}_{o}}{{i}_{1}} = {V}_{o} \times \frac{{R}_{L}}{{m}^{2} {V}_{o}} = \frac{{R}_{L}}{{m}^{2}} \qquad ( Formula 6 )$$

Here, the transformation ratio of the transformer 21C is represented by 1:m. V₁ represents a voltage applied between the ends of the input-side coil 211 of the transformer 21C. V₂ represents a voltage applied between the ends of the output-side coil 212 of the transformer 21C. Also, i₁ represents an electric current that flows through the input-side coil 211 of the transformer 21C. Furthermore, i₂ represents an electric current that flows through the output-side coil 212 of the transformer 21C. Vₒ represents an output voltage of the amplifier 11. R_{L} represents impedance of a load connected to the output terminal 101. Here, each of output impedance seen from the output terminal 12b of the amplifier 12 toward the load and output impedance seen from the output terminal 13b of the amplifier 13 toward the load is in an open state.

As is apparent from Formula 5 and Formula 6, based on a small signal in the band A being input, the amplifier 11 goes into the ON state and the amplifier 12 goes into the OFF state. As a result, the output impedance Z_{c} of the amplifier 11 becomes higher (two times greater) than that observed based on a large signal being input. This in turn enables the amplifier circuit 10C to operate with high efficiency.

In contrast, based on a large signal in the band A being input, both of the amplifiers 11 and 12 go into the ON state. As a result, the amplifier circuit 10C can output a high power signal. Also, because the output impedance Z_{c} of the amplifier 11 becomes lower than (becomes one-half of) that observed based on a small signal being input, the amplifier circuit 10C can suppress signal distortion.

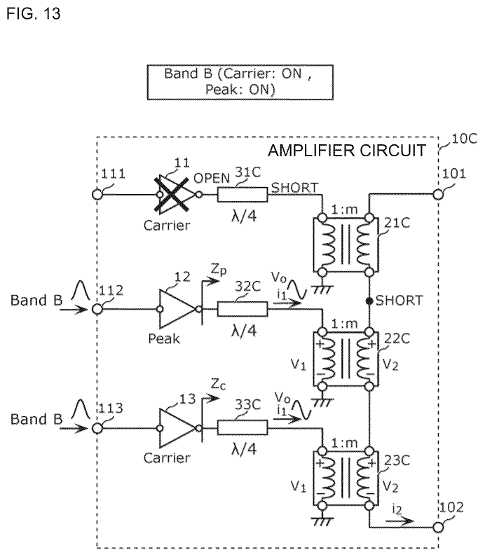

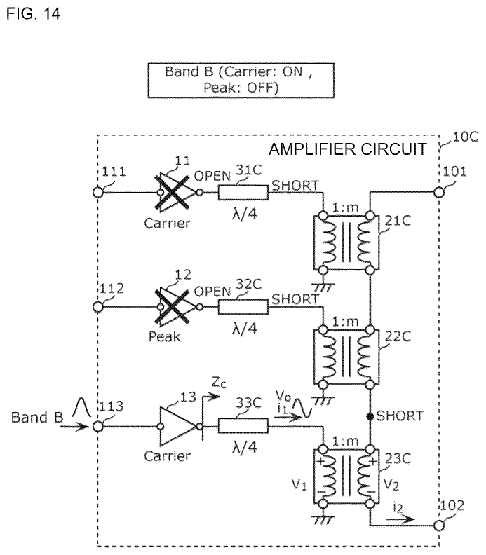

Next, operations performed based on a signal in the band B being input are described with reference to FIGS. 13 and 14.

As illustrated in FIG. 13, based on the power of an input signal in the band B being high (e.g., relative to a power threshold), the amplifiers 12 and 13 operate (ON), and the amplifier 11 does not operate (OFF). In this case, the output impedance Z_{c} seen from the output terminal 13b of the amplifier 13 toward the load and the output impedance Zₚ seen from the output terminal 12b of the amplifier 12 toward the load are expressed by Formula 7 below.

$$[ Math . 7 ]$$

$${V}_{2} = {mV}_{1} = {mV}_{o} \\ {i}_{2} = \frac{1}{m} {i}_{1} \\ {R}_{L} = \frac{{V}_{2} + {V}_{2}}{{i}_{2}} = \frac{{mV}_{o} + {mV}_{o}}{\frac{1}{m} {i}_{1}} = \frac{2 {m}^{2} {V}_{o}}{{i}_{1}} \\ {Z}_{c} = {Z}_{p} = \frac{{V}_{o}}{{i}_{1}} = {V}_{o} \times \frac{{R}_{L}}{2 {m}^{2} {V}_{o}} = \frac{{R}_{L}}{2 {m}^{2}} \qquad ( Formula 7 )$$

Here, the transformation ratio of each of the transformers 22C and 23C is represented by 1:m. V₁ represents a voltage applied between the ends of the input-side coil 221 of the transformer 22C and a voltage applied between the ends of the input-side coil 231 of the transformer 23C. V₂ represents a voltage applied between the ends of the output-side coil 222 of the transformer 22C and a voltage applied between the ends of the output-side coil 232 of the transformer 23C. Also, i₁ represents an electric current that flows through the input-side coil 221 of the transformer 22C and an electric current that flows through the input-side coil 231 of the transformer 23C. Furthermore, i₂ represents an electric current that flows through the output-side coil 222 of the transformer 22C and an electric current that flows through the output-side coil 232 of the transformer 23C. Vₒ represents an output voltage of each of the amplifiers 12 and 13. R_{L} represents the impedance of a load connected to the output terminal 102. Here, output impedance seen from the output terminal 11b of the amplifier 11 toward the load is in an open state.

As illustrated in FIG. 14, based on the power of an input signal in the band B being low, the amplifier 13 operates (ON), and the amplifiers 11 and 12 do not operate (OFF). In this case, the output impedance Z_{c} seen from the output terminal 13b of the amplifier 13 toward the load is represented by Formula 8 below.

$$[ Math . 8 ]$$

$${V}_{2} = {mV}_{1} = {mV}_{o} \\ {i}_{2} = \frac{1}{m} {i}_{1} \\ {R}_{L} = \frac{{V}_{2}}{{i}_{2}} = \frac{{mV}_{o}}{\frac{1}{m} {i}_{1}} = \frac{{m}^{2} {V}_{o}}{{i}_{1}} \\ {Z}_{c} = \frac{{V}_{o}}{{i}_{1}} = {V}_{o} \times \frac{{R}_{L}}{{m}^{2} {V}_{o}} = \frac{{R}_{L}}{{m}^{2}} \qquad ( Formula 8 )$$

Here, the transformation ratio of the transformer 23C is represented by 1:m. V₁ represents a voltage applied between the ends of the input-side coil 231 of the transformer 23C. V₂ represents a voltage applied between the ends of the output-side coil 232 of the transformer 23C. Also, i₁ represents an electric current that flows through the input-side coil 231 of the transformer 23C. Furthermore, i₂ represents an electric current that flows through the output-side coil 232 of the transformer 23C. Vₒ represents an output voltage of the amplifier 13. R_{L} represents the impedance of a load connected to the output terminal 102. Here, each of output impedance seen from the output terminal 11b of the amplifier 11 toward the load and output impedance seen from the output terminal 12b of the amplifier 12 toward the load is in an open state.

As is apparent from Formula 7 and Formula 8, based on a small signal in the band B being input, the amplifier 13 goes into the ON state and the amplifier 12 goes into the OFF state. As a result, the output impedance Z_{c} of the amplifier 13 becomes higher (two times greater) than that observed based on a large signal being input. This in turn enables the amplifier circuit 10C to operate with high efficiency.

On the other hand, based on a large signal in the band B being input, both of the amplifiers 12 and 13 go into the ON state, and the amplifier circuit 10C can output a high power signal. Also, because the output impedance Z_{c} of the amplifier 13 becomes lower than (becomes one-half of) that observed based on a small signal being input, the amplifier circuit 10C can suppress signal distortion.

As described above, in the amplifier circuit 10C, the amplifier 11 functions as a carrier amplifier for the band A, the amplifier 13 functions as a carrier amplifier for the band B, and the amplifier 12 functions as a peak amplifier for the bands A and B. That is, in the amplifier circuit 10C, a dedicated carrier amplifier is provided for each of the bands A and B, and a common peak amplifier is provided for the bands A and B.

### [2.3 Layout of Components of Amplifier Circuit 10C]

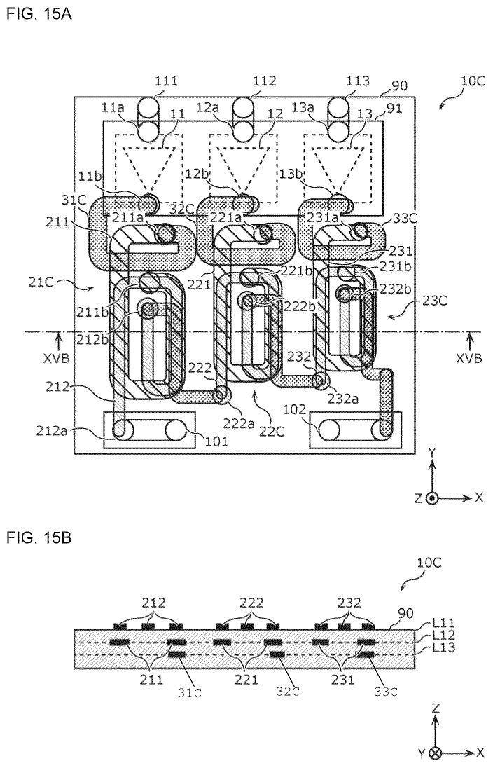

Next, an example of a layout of components of the amplifier circuit 10C according to the present embodiment is described with reference to FIGS. 15A and 15B. FIG. 15A is a plan view of the amplifier circuit 10C according to the present embodiment. FIG. 15B is a cross-sectional view of the amplifier circuit 10C according to the present embodiment.

Specifically, FIG. 15A is a transparent view of a layout of circuit components based on a major surface of a substrate 90 being seen from the positive z-axis direction, and FIG. 15B is a cross-sectional view taken along line XVB-XVB of FIG. 15A. Circuit components in FIG. 15A may be provided with symbols representing their functions to facilitate the understanding of the layout of the circuit components. However, such symbols are not provided on the actual circuit components. Also, in FIGS. 15A and 15B, the illustration of wires connecting the substrate 90 to the circuit components may be omitted.

The amplifier circuit 10C may further include a resin component covering the surfaces of the substrate 90 and the circuit components and a shield electrode layer covering the surface of the resin component. However, the resin component and the shield electrode layer are omitted in FIGS. 15A and 15B.

Similarly to the first embodiment, the amplifiers 11 through 13 are included in the semiconductor IC 91 disposed on the surface of the substrate 90. In plan view of the semiconductor IC 91, the amplifier 12 is disposed between the amplifiers 11 and 13. In FIG. 15A, the output terminals 11b through 13b of the amplifiers 11 through 13 are arranged in this order along the X direction.

The transformers 21C through 23C are formed on the surface of and inside of the substrate 90. In FIGS. 15A and 15B, the output-side coils 212, 222, and 232 of the transformers 21C through 23C are formed on a first layer L11 of the substrate 90 as planar conductors. Also, the input-side coils 211, 221, and 231 of the transformers 21C through 23C are formed in a second layer L12 of the substrate 90 as planar conductors. In plan view of the substrate 90, at least a part of the input-side coil 211 overlaps at least a part of the output-side coil 212, at least a part of the input-side coil 221 overlaps at least a part of the output-side coil 222, and at least a part of the input-side coil 231 overlaps at least a part of the output-side coil 232.

The transmission lines 31C through 33C are formed inside of the substrate 90. In FIGS. 15A and 15B, the transmission lines 31C through 33C are formed in a third layer L13 of the substrate 90 as planar conductors.

The layout of components of the amplifier circuit 10C is not limited to the example illustrated in FIGS. 15A and 15B. For example, the output-side coils 212, 222, and 232 may be formed inside of the substrate 90, and the input-side coils 211, 221, and 231 may be formed on the surface of the substrate 90. Also, the output-side coils 212, 222, and 232 may be formed in different layers, and the input-side coils 211, 221, and 231 may be formed in different layers. Furthermore, each of the input-side coils 211, 221, and 231, the output-side coils 212, 222, and 232, and the transmission lines 31C, 32C, and 33C may be formed across multiple layers.

In addition, any other circuit component included in the radio frequency circuit 1 may also be disposed on or in the substrate 90. Specifically, at least one of the input network 41C, the filters 61 and 62, and the switch 51 may be disposed on or in the substrate 90.

### [2.4 Effects]

As described above, the amplifier circuit 10C according to the present embodiment includes the output terminals 101 and 102, the amplifiers 11 through 13, the transformer 21C including the input-side coil 211 and the output-side coil 212, the transformer 22C including the input-side coil 221 and the output-side coil 222, the transformer 23C including the input-side coil 231 and the output-side coil 232, the transmission line 31C connected to the output terminal 11b of the amplifier 11, the transmission line 32C connected to the output terminal 12b of the amplifier 12, and the transmission line 33C connected to the output terminal 13b of the amplifier 13. The first end 211a of the input-side coil 211 is connected to the output terminal 11b of the amplifier 11 via the transmission line 31C, the second end 211b of the input-side coil 211 is connected to the ground, the first end 212a of the output-side coil 212 is connected to the output terminal 101, the first end 221a of the input-side coil 221 is connected to the output terminal 12b of the amplifier 12 via the transmission line 32C, the second end 221b of the input-side coil 221 is connected to the ground, the first end 222a of the output-side coil 222 is connected to the second end 212b of the output-side coil 212, the first end 231a of the input-side coil 231 is connected to the output terminal 13b of the amplifier 13 via the transmission line 33C, the second end 231b of the input-side coil 231 is connected to the ground, the first end 232a of the output-side coil 232 is connected to the second end 222b of the output-side coil 222, and the second end 232b of the output-side coil 232 is connected to the output terminal 102.

With this configuration, transmission signals in different bands can be amplified by a combination of the amplifiers 11 and 12 and a combination of the amplifiers 12 and 13, and the amplifier circuit 10C can be used as a Doherty amplifier circuit that supports two bands. In this configuration, based on the amplifier 11 being used for one of two bands and the amplifier 13 is used for the other one of the two bands, the amplifier 12 can be used for both of the two bands. Accordingly, compared with a configuration in which two amplifiers are used for each of two bands (i.e., based on the amplifier 12 being implemented by two amplifiers), the above configuration makes it possible to reduce the number of amplifiers included in the amplifier circuit 10C. Furthermore, compared with a configuration in which each of two amplifiers is used for two bands (i.e., based on the amplifiers 11 and 13 being implemented by one amplifier), the above configuration makes it possible to use the amplifiers 11 and 13 each of which has amplification characteristics suitable for the corresponding one of the two bands. In other words, the amplifier circuit 10C according to the present embodiment can be used as a Doherty amplifier circuit and can suppress the increase in the number of amplifiers while reducing the deterioration of amplification characteristics in multiband applications. Also, the present embodiment eliminates the need to input signals with different phases to the amplifier circuit 10C and thereby makes it possible to simplify the input network 41C.

For example, in the amplifier circuit 10C according to the present embodiment, each of the amplifiers 11 and 13 may be a carrier amplifier, and the amplifier 12 may be a peak amplifier.

With this configuration, the amplifier circuit 10C can have two carrier amplifiers each of which supports one of two bands and one peak amplifier that supports the two bands. This in turn makes it possible to use separate carrier amplifiers, each of which operates with either one of a large signal and a small signal, for two bands and use one peak amplifier, which operates only with a large signal, for the two bands. Compared with a case in which one carrier amplifier is used for the two bands, this configuration makes it possible to reduce the deterioration of amplification characteristics.

For example, in the amplifier circuit 10C according to the present embodiment, the amplifier 11 may be capable of amplifying a signal in the band A, the amplifier 13 may be capable of amplifying a signal in the band B, and the amplifier 12 may be capable of amplifying a signal in the band A and a signal in the band B.

This configuration makes it possible to use the amplifier 11 for the band A, the amplifier 13 for the band B, and the amplifier 12 for the bands A and B.

For example, in the amplifier circuit 10C according to the present embodiment, signals in the band A amplified by the amplifiers 11 and 12 may be output via the output terminal 101, and signals in the band B amplified by the amplifiers 12 and 13 may be output via the output terminal 102.

This configuration makes it possible to output a signal in the band A and a signal in the band B from different output terminals and to omit a switch for switching between the bands A and B.

For example, in the amplifier circuit 10C according to the present embodiment, the amplifiers 11 through 13 may be included in one semiconductor IC 91; and in plan view of the semiconductor IC 91, the amplifier 12 may be disposed between the amplifiers 11 and 13.

This configuration makes it possible to implement the amplifiers 11 through 13 with one semiconductor IC 91 and thereby makes it possible to reduce the size of the amplifier circuit 10C. Furthermore, disposing the amplifier 12 between the amplifiers 11 and 13 makes it possible to reduce the lengths of wires that connect the amplifiers 11 through 13 to the output terminals 101 and 102. This in turn makes it possible to reduce wire loss and mismatching loss caused by stray capacitance of wires and thereby makes it possible to improve the characteristics of the amplifier circuit 10C.

Also, the radio frequency circuit 1C according to the present embodiment includes the amplifier circuit 10C, the filter 61 that is connected to the output terminal 101 and has a pass band including the band A, and the filter 62 that is connected to the output terminal 102 and has a pass band including the band B.

This makes it possible to provide the radio frequency circuit 1C having the effects of the amplifier circuit 10C described above.

### First Variation of Second Embodiment

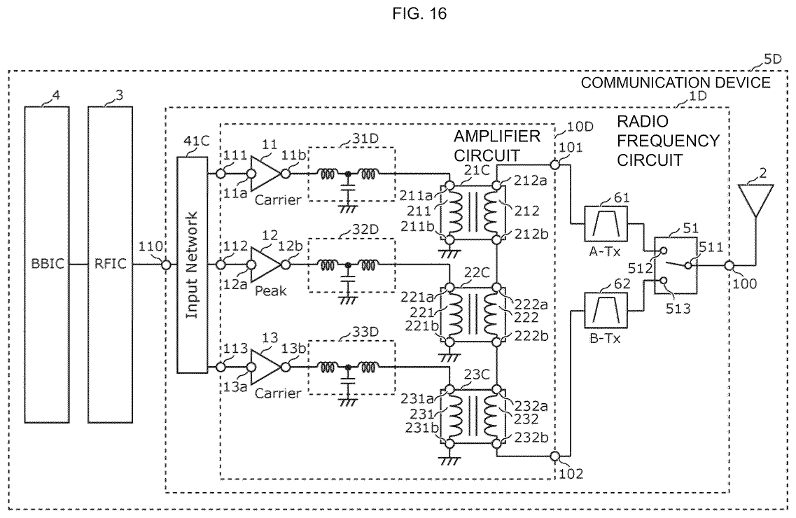

Next, a first variation of the second embodiment is described. This variation mainly differs from the second embodiment in the configuration of transmission lines. Below, differences between this variation and the second embodiment are mainly described with reference to FIG. 16.

FIG. 16 is a circuit diagram of an amplifier circuit 10D, a radio frequency circuit 1D, and a communication device 5D according to this variation. The communication device 5D differs from the communication device 5C of the second embodiment in that the radio frequency circuit 1D is provided in place of the radio frequency circuit 1C. The radio frequency circuit 1D differs from the radio frequency circuit 1C of the second embodiment in that the amplifier circuit 10D is provided in place of the amplifier circuit 10C. The amplifier circuit 10D differs from the amplifier circuit 10C of the second embodiment in that transmission lines 31D through 33D are provided in place of the transmission lines 31C through 33C.

Each of the transmission lines 31D through 33D may also be referred to as a phase adjuster or a phase shifter. Similarly to the transmission line 31C, the transmission line 31D is connected between the output terminal 11b of the amplifier 11 and the first end 211a of the input-side coil 211 of the transformer 21C. Similarly to the transmission line 32C, the transmission line 32D is connected between the output terminal 12b of the amplifier 12 and the first end 221a of the input-side coil 221 of the transformer 22C. Similarly to the transmission line 33C, the transmission line 33D is connected between the output terminal 13b of the amplifier 13 and the first end 231a of the input-side coil 231 of the transformer 23C.

As illustrated in FIG. 16, each of the transmission lines 31D through 33D includes two inductors and a capacitor. The two inductors are series arm elements and function as so-called series inductors. On the other hand, the capacitor is a parallel arm element and functions as a so-called shunt capacitor. With this configuration, each of the transmission lines 31D through 33D can shift the phases of signals in the band A and/or the band B by −90 degrees (or delay the phases by 90 degrees).

The internal configuration of each of the transmission lines 31D through 33D is not limited to the example illustrated in in FIG. 16. For example, the capacitor may be a series arm element, and at least one of the two inductors may be a parallel arm element. Also, each of the transmission lines 31D through 33D may be configured to include only one of an inductor and a capacitor. That is, each of the transmission lines 31D through 33D may include at least one of an inductor and a capacitor.

As described above, in the amplifier circuit 10D of this variation, each of the transmission lines 31D, 32D, and 33D includes at least one of an inductor and a capacitor.

This configuration makes it possible to use an inductor and/or a capacitor for each of the transmission lines 31D through 33D and thereby makes it possible to reduce the length of each of the transmission lines 31D through 33D.

In this variation, it is not necessary to provide an inductor and/or a capacitor in each of the transmission lines 31D, 32D, and 33D. That is, it is also possible to configure only one or two of the transmission lines 31D, 32D, and 33D to include an inductor and/or a capacitor.

### Second Variation of Second Embodiment

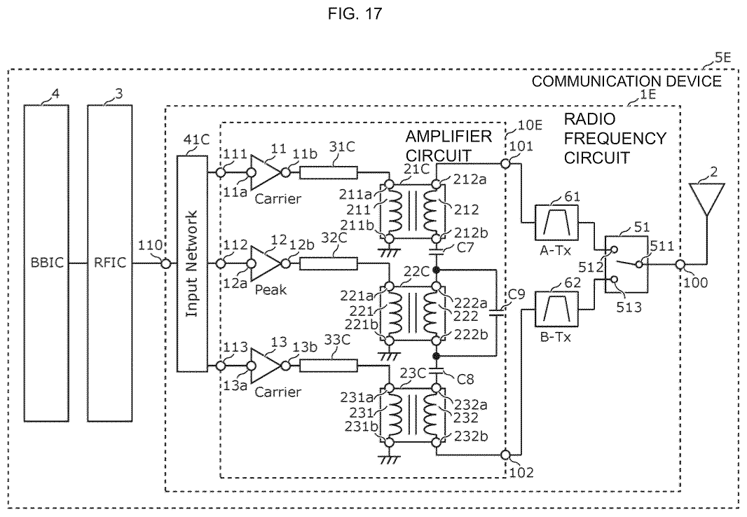

Next, a second variation of the second embodiment is described. This variation mainly differs from the second embodiment in that capacitors are connected to the transformer 22C. Below, differences between this variation and the second embodiment are mainly described with reference to FIG. 17.

FIG. 17 is a circuit diagram of an amplifier circuit 10E, a radio frequency circuit 1E, and a communication device 5E according to this variation. The communication device 5E differs from the communication device 5C of the second embodiment in that the radio frequency circuit 1E is provided in place of the radio frequency circuit 1C. The radio frequency circuit 1E differs from the radio frequency circuit 1C of the second embodiment in that the amplifier circuit 10E is provided in place of the amplifier circuit 10C. The amplifier circuit 10E differs from the amplifier circuit 10C of the second embodiment in that capacitors C7 through C9 are provided.

The capacitor C7 is connected between the second end 212b of the output-side coil 212 and the first end 222a of the output-side coil 222. Specifically, one end of the capacitor C7 is connected to the second end 212b of the output-side coil 212, and another end of the capacitor C7 is connected to the first end 222a of the output-side coil 222.

The capacitor C8 is connected between the second end 222b of the output-side coil 222 and the first end 232a of the output-side coil 232. Specifically, one end of the capacitor C8 is connected to the second end 222b of the output-side coil 222, and another end of the capacitor C8 is connected to the first end 232a of the output-side coil 232.

One end of the capacitor C9 is connected to the first end 222a of the output-side coil 222, and another end of the capacitor C9 is connected to the second end 222b of the output-side coil 222.

As described above, the amplifier circuit 10E according to this variation may include the capacitor C7 connected between the second end 212b of the output-side coil 212 and the first end 222a of the output-side coil 222.

This configuration makes it possible to absorb a difference between the phase of a signal in the band A adjusted by the transmission line 31C and the phase of a signal in the band A adjusted by the transmission line 32C.

Also, for example, the amplifier circuit 10E according to this variation may include the capacitor C8 connected between the second end 222b of the output-side coil 222 and the first end 232a of the output-side coil 232.

This configuration makes it possible to absorb a difference between the phase of a signal in the band B adjusted by the transmission line 32C and the phase of a signal in the band B adjusted by the transmission line 33C.

Also, for example, the amplifier circuit 10E according to this variation may include the capacitor C9 one end of which is connected to the first end 222a of the output-side coil 222 and another end of which is connected to the second end 222b of the output-side coil 222.

This configuration makes it possible to ensure that the output-side coil 222 is short-circuited on the side of the first end 222a or the second end 222b based on the amplifier 12 not operating.

### Other Embodiments

Amplifier circuits, radio frequency circuits, and communication devices according to embodiments of the present disclosure are described above. However, the present disclosure is not limited to the amplifier circuits, the radio frequency circuits, and the communication devices of the above embodiments. The present disclosure may also include other embodiments implemented by combining components in the above-described embodiments, variations obtained by making various modifications conceivable by a person skilled in the art to the embodiments without departing from the spirit of the present disclosure, and various devices including the radio frequency circuits described above.

For example, in the circuit configurations of the amplifier circuits, the radio frequency circuits, and the communication devices according to the embodiments described above, another circuit element and/or a wire may be inserted in a path connecting circuit elements and signal paths illustrated in the drawings. For example, an impedance matching circuit may be inserted between the filter 61 and the amplifier circuit 10 and/or between the filter 62 and the amplifier circuit 10. Also, an impedance matching circuit may be inserted between the filter 61 and the switch 51 and/or between the filter 62 and the switch 51. Similarly, an impedance matching circuit may be inserted between any other circuit elements. An impedance matching circuit may be comprised of, for example, an inductor and/or a capacitor. A circuit element that can be inserted is not limited to a circuit element constituting an impedance matching circuit.

### INDUSTRIAL APPLICABILITY

The present disclosure can be widely used for communication devices, such as mobile phones, as an amplifier circuit or a radio frequency circuit disposed in a multiband front-end unit.

### REFERENCE SIGNS LIST

1, 1A, 1B, 1C, 1D, 1E radio frequency circuit
2 antenna
3 RFIC
4 BBIC
5, 5A, 5B, 5C, 5D, 5E communication device
10, 10A, 10B, 10C, 10D, 10E amplifier circuit
11, 12, 13 amplifier
11a, 12a, 13a, 111, 112, 113 input terminal
11b, 12b, 13b, 101, 102 output terminal
21, 21C, 22, 22C, 23C transformer
31, 31A, 31B, 31C, 31D, 32B, 32C, 32D, 33C, 33D transmission line
41, 41C input network
51 switch
61, 62 filter
90 substrate
91 semiconductor IC
100 antenna connection terminal
110 radio frequency input terminal
211, 221, 231 input-side coil
211a, 221a, 231a first end of input-side coil
211b, 221b, 231b second end of input-side coil
212, 222, 232 output-side coil
212a, 222a, 232a first end of output-side coil
212b, 222b, 232b second end of output-side coil
C1, C2, C3, C4, C5, C6, C7, C8, C9 capacitor
L1, L2, L5, L6 inductor
L3, L4 coil

1. An amplifier circuit comprising:
a first output terminal and a second output terminal;
a first amplifier, a second amplifier, and a third amplifier;
a first transformer including a first input-side coil and a first output-side coil;
a second transformer including a second input-side coil and a second output-side coil; and
a transmission line connected to an output terminal of the second amplifier, wherein
a first end of the first input-side coil is connected to an output terminal of the first amplifier;
a second end of the first input-side coil is connected to the output terminal of the second amplifier via the transmission line;
a first end of the second input-side coil is connected to an output terminal of the third amplifier;
a second end of the second input-side coil is connected to the output terminal of the second amplifier via the transmission line;
a first end of the first output-side coil is connected to the first output terminal;
a second end of the first output-side coil is connected to a ground;
a first end of the second output-side coil is connected to the second output terminal; and
a second end of the second output-side coil is connected to the ground.

2. The amplifier circuit according to claim 1, wherein
each of the first amplifier and the third amplifier is a carrier amplifier; and
the second amplifier is a peak amplifier.

3. The amplifier circuit according to claim 2, wherein
the first amplifier is configured to amplify a signal in a first band;
the third amplifier is configured to amplify a signal in a second band; and
the second amplifier is configured to amplify a signal in the first band and a signal in the second band.

4. The amplifier circuit according to claim 3, wherein
the signals in the first band amplified by the first amplifier and the second amplifier are output via the first output terminal; and
the signals in the second band amplified by the second amplifier and the third amplifier are output via the second output terminal.

5. The amplifier circuit according to claim 4, wherein
the transmission line includes at least one of an inductor and a capacitor.

6. The amplifier circuit according to claim 5, wherein
the transmission line includes
a first transmission line connected between the output terminal of the second amplifier and the second end of the first input-side coil, and
a second transmission line connected between the output terminal of the second amplifier and the second end of the second input-side coil.

7. The amplifier circuit according to claim 5, wherein
the first amplifier, the second amplifier, and the third amplifier are included in one integrated circuit; and
in plan view of the integrated circuit, the second amplifier is disposed between the first amplifier and the third amplifier.

8. A radio frequency circuit comprising:
the amplifier circuit according to claim 7;
a first filter that is connected to the first output terminal and has a pass band including the first band; and
a second filter that is connected to the second output terminal and has a pass band including the second band.

9. An amplifier circuit comprising:
a first output terminal and a second output terminal;
a first amplifier, a second amplifier, and a third amplifier;
a first transformer including a first input-side coil and a first output-side coil;
a second transformer including a second input-side coil and a second output-side coil;
a third transformer including a third input-side coil and a third output-side coil;
a first transmission line connected to an output terminal of the first amplifier;
a second transmission line connected to an output terminal of the second amplifier; and
a third transmission line connected to an output terminal of the third amplifier, wherein
a first end of the first input-side coil is connected to the output terminal of the first amplifier via the first transmission line;
a second end of the first input-side coil is connected to a ground;
a first end of the first output-side coil is connected to the first output terminal;
a first end of the second input-side coil is connected to the output terminal of the second amplifier via the second transmission line;
a second end of the second input-side coil is connected to the ground;
a first end of the second output-side coil is connected to a second end of the first output-side coil;
a first end of the third input-side coil is connected to the output terminal of the third amplifier via the third transmission line;
a second end of the third input-side coil is connected to the ground;
a first end of the third output-side coil is connected to a second end of the second output-side coil; and
a second end of the third output-side coil is connected to the second output terminal.

10. The amplifier circuit according to claim 9, wherein
each of the first amplifier and the third amplifier is a carrier amplifier; and
the second amplifier is a peak amplifier.

11. The amplifier circuit according to claim 10, wherein
the first amplifier is configured to amplify a signal in a first band;
the third amplifier is configured to amplify a signal in a second band; and
the second amplifier is configured to amplify a signal in the first band and a signal in the second band.

12. The amplifier circuit according to claim 11, wherein
the signals in the first band amplified by the first amplifier and the second amplifier are output via the first output terminal; and
the signals in the second band amplified by the second amplifier and the third amplifier are output via the second output terminal.

13. The amplifier circuit according to claim 12, wherein
the first transmission line includes at least one of an inductor and a capacitor.

14. The amplifier circuit according to claim 13, wherein
the second transmission line includes at least one of an inductor and a capacitor.

15. The amplifier circuit according to claim 14, wherein
the third transmission line includes at least one of an inductor and a capacitor.

16. The amplifier circuit according to claim 15, further comprising:
a capacitor connected between the second end of the first output-side coil and the first end of the second output-side coil.

17. The amplifier circuit according to claim 16, further comprising:
a capacitor connected between the second end of the second output-side coil and the first end of the third output-side coil.

18. The amplifier circuit according to claim 17, further comprising:
a capacitor one end of which is connected to the first end of the second output-side coil and another end of which is connected to the second end of the second output-side coil.

19. The amplifier circuit according to claim 18, wherein
the first amplifier, the second amplifier, and the third amplifier are included in one integrated circuit; and
in plan view of the integrated circuit, the second amplifier is disposed between the first amplifier and the third amplifier.

20. A radio frequency circuit comprising:
the amplifier circuit according to claim 9;
a first filter that is connected to the first output terminal and has a pass band including the first band; and
a second filter that is connected to the second output terminal and has a pass band including the second band.
